(19) United States
(12) Patent Application Publication
(10) Pub. No.: US 2026/0135532 A1
(43) Pub. Date: May 14, 2026

(54) FREQUENCY DETECTION AND FREQUENCY-RESPONSE FLATNESS COMPENSATION IN AMPLIFIER SYSTEMS

(71) Applicant: OPHIR RF, INC., LOS ANGELES, CA (US)

(72) Inventors: STEPHEN D. WHITE, NORTH LAS VEGAS, NV (US); FEIYU WANG, LOS ANGELES, CA (US)

(21) Appl. No.: 18/943,713

(22) Filed: Nov. 11, 2024

(51) Int. Cl. H03G 3/30; G01R 31/28; H03F 3/24

(52) U.S. Cl. CPC H03G 3/3042; G01R 31/2822; H03F 3/245; H03F 2200/451

(57) ABSTRACT

A scheme for frequency detection and flatness compensation in electronics systems such as amplifiers is presented. A circuit for automatic detection of a frequency in a radio frequency (RF) input signal is used to determine a frequency-response flatness compensation, and adjust a gain of the overall system to improve flatness errors. Where a power meter is used to measure power levels of RF output signals, automatic input of a detected frequency is applied to the power meter to negate having to input the frequency to the power meter to be used for a given power measurement. The scheme may also perform frequency-response flatness compensation to address flatness errors that are introduced from automatic level control circuit elements that maintain a consistent power level.

### FIELD OF THE INVENTION

The present invention relates to radio frequency (RF) and power electronics systems. Specifically, the present invention relates to a scheme for automatic frequency detection and frequency response compensation to improve flatness errors in an output of a power amplifier, an automatic frequency input for a power meter, and a scheme for frequency response compensation for flatness errors using automatic level control components for maintaining a constant power level that are integrated into amplifier circuit design.

### BACKGROUND OF THE INVENTION

Many radio frequency (RF) and microwave power amplifiers for laboratory use, wireless communications, radar, and other applications require operation over a wide band of frequencies. In the current state of the art, the gain and output power of such wideband amplifiers varies as a function of frequency (i.e., is not flat). For some applications, this variation is problematic. In a basic amplifier, there is simply an RF input and RF output, with the frequency response tuned optimally for the band of operation by various means at the circuit level. Even when tuned optimally, as the frequency band widens the flatness generally degrades. Microcontrollers in control circuitry within such power amplifiers may contain a lookup table or other function based on a calibration procedure performed with the amplifier that contains information equating a detected output voltage to an RF output power level. The user inputs the desired output power level to the microcontroller, and then adjusts the control voltage to a variable gain amplifier (VGA) so that the gain is what is needed to obtain the desired output power.

To mitigate the problem of requiring a manual user input, some power amplifiers have built-in power meters and/or control functions to maintain a constant power level, commonly referred to as Automatic Level Control or ALC. Power meters are a category of commonly-used test instruments for RF and microwave devices. Such power meters can be standalone instruments, or they can be integrated in equipment including power amplifiers. Due to the wide range of frequencies covered by such instruments, and the inherent issues with having a uniform (flat) frequency response under such conditions, it is common for these instruments to also have a calibration table integral to the instrument that compensates for lack of flatness in frequency. The user must input to the instrument the frequency to be used for a given power measurement. If the instrument is routinely used for measurements of signals with multiple frequencies, then the frequency must be input to the instrument prior to subsequent measurements.

One issue with such built-in power output control features is that they may work quite well at a specific frequency (typically, the frequency at which they are calibrated), but exhibit errors at other frequencies due at least to imperfections in the response as a function of the flatness of the power meter and ALC components themselves, as these components often limit the overall flatness of the system. Also, the speed at which an ALC function can operate is often limited by the nature of the RF signal. For example, if the ALC operates at a speed that is fast relative to the frequency of amplitude modulation, then the ALC would “strip-off” that modulation.

The calibration procedures to adjust the gain of the VGA are typically performed at a single frequency at the center of the frequency range of the amplifier. Where power meters or ALC functions are involved, and all components in a control loop have the exact characteristics exhibited at the frequency at which the system was calibrated for all frequencies of interest, the power meter and ALC functions should be accurate at all of those frequencies. However, if the RF components in the control loop (such as the coupler, detector and associated cables) do not have constant characteristics at other frequencies (i.e., they are not flat), errors will be introduced at those frequencies. In most cases however, especially for wideband applications, these components are not perfectly flat, and therefore errors occur. In many demanding applications, where accuracy in frequency readings and power levels are required across a broad range of frequencies, external equipment and possibly manual intervention is required to obtain the needed results.

Accordingly, there is a need in the art to improve both the flatness of the frequency response, and the flatness of the power output level, in wideband RF and microwave power amplifiers.

### BRIEF SUMMARY OF THE INVENTION

The present invention is a scheme that includes elements of frequency detection and frequency-response flatness compensation that are embodied in one or more circuits that are implemented in wideband and broadband power electronics systems, for example circuits that are integrated into power amplifiers. According to one embodiment of thereof, the present invention is a scheme for automatic frequency detection and frequency-response flatness compensation that negates a requirement for a user to manually input a frequency to an amplifier system for flatness compensation, thus realizing improvements in performance by minimizing errors due to flatness in the frequency response of the amplifier.

The present invention is, according to one embodiment thereof, a frequency-response flatness compensation scheme, in one or more systems and methods for automatically determining a frequency, thus negating the requirement for the user to manually input the frequency to the amplifier. Such a frequency response compensation scheme improves errors due to flatness in the frequency response of the amplifier. The present invention is therefore comprised of one or more systems and methods that automatically detect a frequency of an input signal, determine an appropriate flatness compensation in response to the detected frequency, and perform gain control by adjusting a gain of a variable gain amplifier based on a sample of the radio frequency (RF) input signal.

The present invention is also, according to a further embodiment thereof, a scheme for an automatic input of frequency where power meters are used to regulate an output power of an amplifier system according to a power level of the RF input signal. This scheme also negates a need for a user to manually enter frequency information to the power meter and enables follow-on gain control where automatic level control circuit elements are utilized to obtain an appropriate output power.

The present invention is also, according to another embodiment thereof, a scheme for performing frequency-response flatness compensation due to errors introduced into amplifier systems from characteristics of automatic level control circuit elements.

It is therefore one objective of the present invention to provide an approach for automatic detection of a frequency of an input signal, for power electronics systems such as power amplifiers and other wideband or broadband applications. It is another objective of the present invention to utilize the automatically detected frequency to determine a frequency-response flatness compensation, and adjust a gain of the overall system to improve flatness errors. It is still another objective to provide an approach for automatic input of a frequency where power meters are used to ensure that output power is proportional to a power in the RF input signal. It is still a further objective of the present invention to provide an approach that determines a frequency-response flatness compensation where automatic level control circuit elements are used to address power considerations between the RF input and the RF output, and to adjust a gain of the overall system to improve flatness errors introduced by characteristics of such automatic level control circuit elements. It is yet another objective of the present invention to provide circuits for performing each of the above objectives and to integrate such circuits into power meters, power amplifiers and other power electronics systems.

Other objects, embodiments, features and advantages of the present invention will become apparent from the following description of the embodiments, taken together with the accompanying drawings, which illustrate, by way of example, the principles of the invention.

### BRIEF DESCRIPTION OF THE SEVERAL VIEWS OF THE DRAWINGS

The accompanying drawings, which are incorporated in and constitute a part of this specification, illustrate several embodiments of the invention and together with the description, serve to explain the principles of the invention. The noted frequencies and signal levels are for the purposes of illustration, and may be tailored to the needs of a specific application.

FIG. 1 is a diagram for a scheme for automatic frequency detection and frequency-response flatness compensation according to one embodiment of the present invention;

FIG. 2 is a diagram of a scheme for calibration of gain measurement components of an amplifier, according to the embodiment of FIG. 1;

FIG. 3 is a flow chart illustrating steps in a process of automatically detecting a frequency, determining a frequency-response flatness compensation, and performing gain control according to the embodiment of FIG. 1;

FIG. 4 is a diagram for a scheme for automatic detection and input of a frequency for measurements performed by a power meter, according to another embodiment of the present invention;

FIG. 5 is a flow chart illustrating steps in a process of automatically detecting and inputting a frequency for measurements performed by a power meter according to the embodiment of FIG. 4;

FIG. 6 is a diagram for a scheme for frequency-response flatness compensation for characteristics of automatic level control circuit elements, according to yet another embodiment of the present invention; and

FIG. 7 is a flow chart illustrating steps in a process of determining a frequency-response flatness compensation for characteristics of automatic level control circuit elements, and performing gain control to improve flatness introduced due to such automatic level control circuit elements, according to the embodiment of FIG. 6.

### DETAILED DESCRIPTION OF THE INVENTION

In the following description of the present invention reference is made to the exemplary embodiments illustrating the principles of the present invention and how it is practiced. Other embodiments will be utilized to practice the present invention and structural and functional changes will be made thereto without departing from the scope of the present invention.

The present invention is a scheme for frequency detection and flatness compensation in electronics systems such as amplifiers. In one embodiment, an automatic detection of a frequency in the RF input signal is used to determine frequency-response flatness compensation, and adjust the gain of the overall system to improve flatness errors. In a further embodiment, where a power meter is used to measure power levels of incoming RF input signals, automatic input of a detected frequency is applied to the power meter to negate having to input the frequency to the power meter to be used for a given power measurement. In still a further embodiment, frequency-response flatness compensation is performed specifically to address flatness errors that are introduced from automatic level control circuit elements that maintain a constant or consistent power level by ensuring proportionality between input and output power levels.

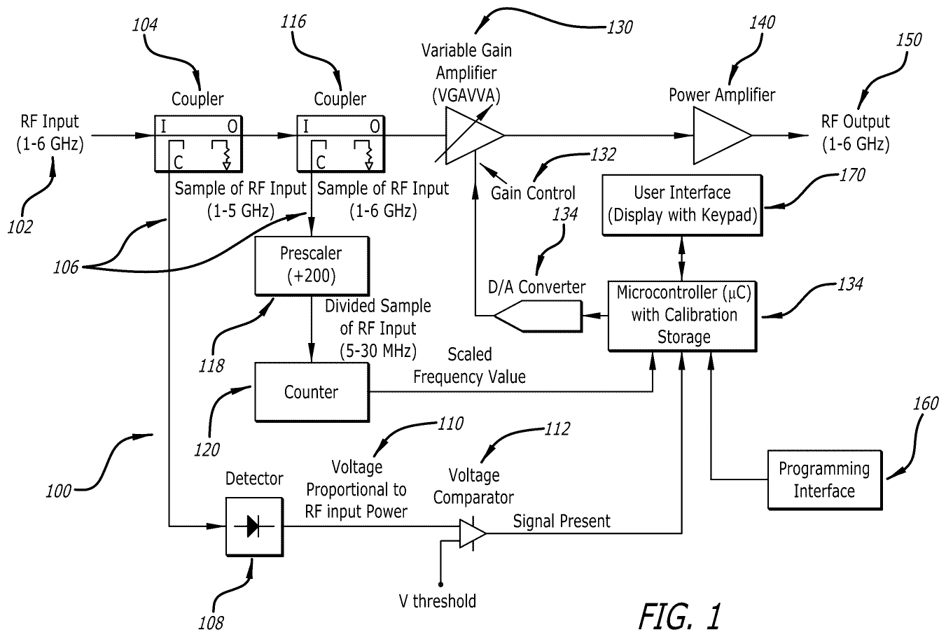

FIG. 1 is a diagram illustrating a circuit 100 that provides a scheme for automatic frequency detection, frequency-response flatness compensation, and corresponding gain control. The circuit 100 of FIG. 1 may be integrated into a broader system such as in a wideband or broadband power amplifier, or in other applications and systems in electronics. The circuit 100 of FIG. 1 provides this scheme to correct inherent flatness errors (i.e., correcting for deviations in flatness and flatness degradation of the frequency response) at a desired operational frequency that result from variances in gain and output power as a function of operation over a wide band of frequencies. The circuit 100 of FIG. 1 may be comprised of several sub-circuits, each of which perform specific functions; regardless, the functions performed generally by the circuit 100 include automatically detecting a frequency of an input signal, determining a flatness compensation in response to the detected frequency, and performing gain control to realize improvements in degradations due to a lack of flatness in the frequency response of power electronics systems.

It is to be noted that any amplitude and frequency notations in FIG. 1 are provided for example only, and that the actual configuration and values will vary by application within which the circuit 100 is implemented. It is therefore to be understood that the present invention is not to be limited to any such notation or example illustrated in the drawings or discussed herein.

In the circuit 100 of the present invention, a radio frequency (RF) input signal 102 is fed to a first coupler 104. The first coupler 104 is a circuit element that is part of a signal sampling sequence or sub-circuit, in which samples of the RF input signal 102 are provided to other circuit elements as described herein to perform the automatic frequency detection function of the circuit 100. The first coupler 104 captures a sample 106 of the RF input signal 102 and provides this sample 106 to a detector 108. The detector 108 is a circuit element that generates a voltage 110 representing the input power that is proportional to a signal level of the RF input signal 102.

This voltage 110 is then presented to a voltage comparator 112 that determines whether sufficient signal is present to be processed in a frequency-response flatness compensation sequence of the circuit 100 described further below. If the signal level is above a detection threshold value, compensation is provided; if not, a microcontroller 114 sets a gain 132 of a variable gain amplifier 130 via a digital-to-analog converter 134 to a nominal value so that a broader application implementing the circuit 100 (for example, a power amplifier 140) can operate, but without frequency-response flatness compensation.

The circuit 100 sends the sample 106 of the RF input signal 102 from the first coupler 104 to a second coupler 116. The second coupler 116 is a circuit element that is part of a signal processing sequence, or sub-circuit, in which samples 106 of the RF input signal 102 via coupler 116 are provided to additional circuit elements as described herein to perform the frequency-response flatness compensation function of the circuit 100. The second coupler 116 provides the sample 106 of the RF input signal 102 to a prescaler 118. The prescaler 118 is a circuit element that divides the high frequency of the RF input signal 102 down to a value that can be processed by other digital circuit elements in the circuit 100. For example, where the RF input signal 102 has a frequency range of 1-6 GHz, the prescaler 118 divides the 1-6 GHz RF input signal 102 down to 5-30 MHz so that it can be processed, or measured, by a counter 120. The counter 120 measures an output of the prescaler 118 representing the RF input signal 102 to generate a measured signal for the microcontroller 114. The microcontroller 114 then selects a value stored in a lookup table that is either closest to a pre-selected sample point from the measured signal (or an interpolation between the closest two sample points), and which represents a deviation from flatness at that frequency; the lookup table therefore identifies a value representing how much gain 132 the variable gain amplifier 130 needs to be adjusted by to match the overall amplifier gain to a reference level. Note that this process is performed only if the input signal level is above the detection threshold determined by voltage comparator 112.

In this example, the frequency information is used to select a value stored in a lookup table generated by a pre-processing calibration sequence described further below that is closest to a 25 MHz-spaced sample point.

Examples are as follows:

| | | Lookup | |
|---|---|---|---|
| Input Frequency | Nearest Lookup | Table Center | Example Table |
| (MHz) | Table Entry | Frequency | Value (dB) |
| 1,000 | 1 | 1,000 | 6.0 |
| 6,000 | 201 | 6,000 | 0 |
| 1,020 | 2 | 1,025 | 5.80 |
| 1,080 | 4 | 1,075 | 5.68 |

It is to be understood that the concept above is not to be limited to any particular frequency range or calibration technique. In the example above of a power amplifier operating in the 1-6 GHz range, the typical peak-to-peak flatness (passband ripple) may be in the range of several dB. A network analyzer, described further herein with regard to the pre-processing calibration sequence, measures the frequency response over the selected frequency range and generates a file containing the amplitude of the gain at many points across that range. The number of sample points depends on the network analyzer used, and may be programmable. For this example, the number of sample points is 201 (a typical value used by many network analyzers), resulting in a file containing the gain as a function of frequency at 201 points, or a data point approximately every 25 MHz ((6,000-1,000 MHz)/201 points). Therefore, the pre-selected sample point of 25 MHz may change, and depends at least in part on characteristics of circuit elements utilized; but it is to be understood that pre-selected sample points may have any value, and therefore the present invention is not to be limited to any specific value of a pre-selected sample point referenced herein.

Once the steps outlined above are performed to detect the frequency and determine the closest entry in the lookup table thereto (or an interpolation between the closest two sample points), a gain control sequence, or sub-circuit, is performed by the circuit 100. In this sequence, the gain 132 of the variable gain amplifier 130 is adjusted by the selected value from the lookup table by the digital-to-analog converter 134. The variable gain amplifier 130 is therefore adjusted by the microcontroller 114 in response to the frequency-response flatness compensation function to correct inherent flatness degradation errors at a desired operational frequency, by reducing a gain 132 of the variable gain amplifier 130 by the value in the lookup table selected by the microcontroller 114 that is closest to the pre-selected sample point (or as noted above, an interpolation between the closest two sample points). An RF output signal 150 of the power amplifier 140 therefore exhibits a frequency response that is corrected for flatness at the desired operational frequency. Note that in this example an analog variable gain amplifier is depicted, whereas a digital version may also be used.

Using an example of an input frequency of 1,080 MHz, table entry 4 would be selected as it is closer to 1,075 MHz than any other table entry. The gain 132 of the variable gain amplifier 130 would be reduced by 5.68 dB to match the overall gain of the amplifier system, to the reference level (at 6,000 MHz in this example).

After the processes are performed by the circuit elements above, the gain at each of the frequencies corresponding to an entry in the lookout table represents a compensation adjustment that results in the same overall system gain, thus resulting in a flat frequency response. Therefore, together with the pre-processing calibration sequence described below, the circuit 100 ensures that the gain at the output of the variable gain amplifier 130 matches the overall amplifier gain, and therefore exhibits a frequency-response flatness at any frequency of the RF input signal 102. Since this function is dependent only on the frequency of the RF input signal 602, and not on any measured output amplitude, it can operate relatively quickly without impacting any AM modulation on the signal 602 at the RF input.

The novel frequency response compensation scheme described herein has been demonstrated to take a power amplifier covering the range of 1-6 GHz with an uncorrected (open-loop, or uncompensated) flatness (or, passband ripple) of around 10 dB to having a flatness of less than 0.5 dB with correction enabled.

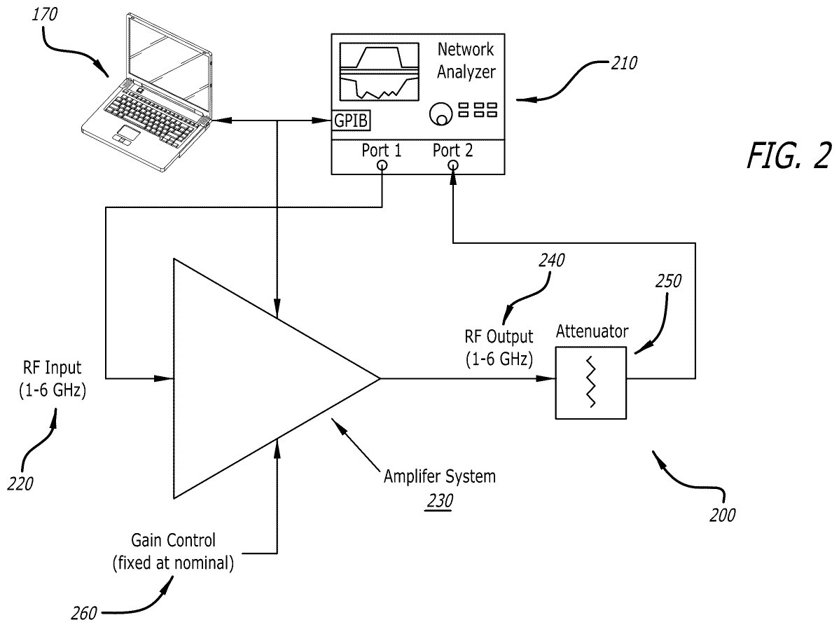

As noted above, the present invention may include a pre-processing calibration sequence. FIG. 2 is a diagram illustrating a gain measurement setup 200 that performs such pre-processing calibration. Prior to performing the automatic frequency detection, frequency-response flatness compensation, and gain control functions described above with regard to FIG. 1 in a wideband power amplifier (or other application or systems), the amplifier may be calibrated using the gain measurement setup 200 of FIG. 2.

It is to be understood that the calibration performed in the pre-processing calibration sequence may be accomplished in multiple ways, such as for example with a network analyzer as illustrated in FIG. 2, or with a signal generator and a power meter. Regardless, FIG. 2 illustrates a gain measurement setup 200 that includes a network analyzer 210, which drives a signal into an input 220 of a power amplifier system 230, and monitors the output 240 via an attenuator 250. In FIG. 2, the power amplifier system 230 is connected to the network analyzer 210 using the attenuator 250 to protect the network analyzer 210 from being damaged by the high-power output 240 of the power amplifier system 230. During calibration, a gain control input 260 of the system is set to a fixed value. Referring to FIG. 1, during application of the gain measurement setup 200, the variable gain amplifier 130 is set to a constant value via a setting of the digital-to-analog converter 134 from the microcontroller 114. Use of a fixed gain at the gain control input 260 results in the power amplifier system 230 being in its uncompensated or open-loop configuration.

Continuing with the example above for a power amplifier operating in a frequency range is 1-6 GHz (1,000-6,000 MHz), the typical peak-to-peak flatness (or passband ripple) may be in the range of several dB. The network analyzer 210 measures the frequency response over the selected frequency range, and generates a file containing the magnitude of the gain at many points across that range. Referring to FIG. 1, this file is then provided to the microcontroller 114 via a programming interface 160 and software application. The programming interface 160 may be one of many interfaces, including (but not limited to) Ethernet, GPIB (IEEE-488), USB, RS-232, RS-422, or even a manually-entry user interface 180 such as a keypad, keyboard, or touchscreen or other type of display.

Once the frequency response file, which contains absolute gain versus frequency, is loaded into the microcontroller 114 via the programming interface 160 and software application, a lookup table is generated containing the values of the deviation from flatness. In the 1-6 GHz example, assume that the peak-to-peak deviation in gain from 1-6 GHz was 6 dB. The lookup table then has values ranging from zero to 6 dB, with zero corresponding to a reference value of the absolute gain, which may be the average, maximum or minimum value, depending on the specific algorithm used. This lookup table can be prepared whenever the microcontroller 114 is booted using the stored absolute frequency response data, or prepared when the file is loaded, and the deviation values stored.

It is to be understood that variations in gain at frequencies between the calibration points stored in the lookup table are possible. Therefore, more calibration points may result in a smoother overall frequency response. Neither the claims nor this specification are therefore intended to be limited by any specific number of calibration or sample points referenced herein.

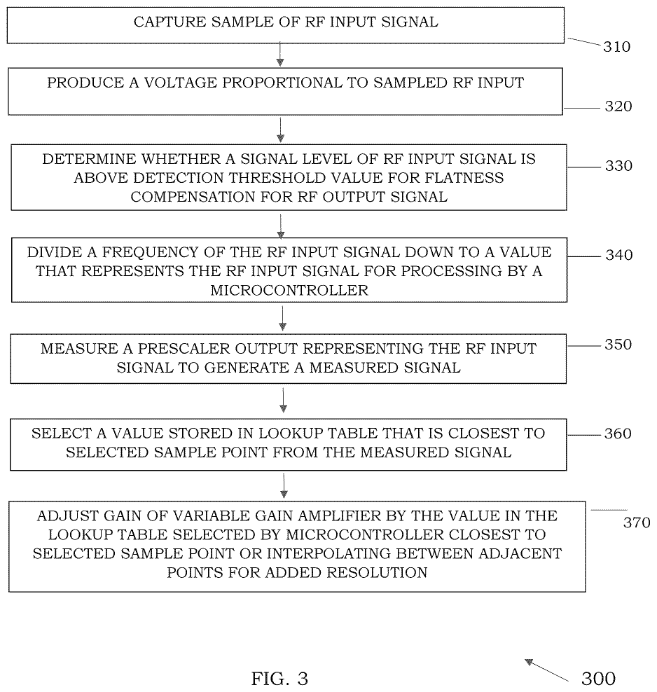

FIG. 3 is a flowchart comprising steps in a process 300 of performing the present invention according to the embodiment of FIG. 1 and FIG. 2 for automatic frequency detection and frequency-response flatness compensation to correct inherent flatness errors at a desired frequency in an amplifier circuit. The process 300 begins with an automatic frequency detection sequence at step 310 by capturing a sample of a RF input signal at a first coupler. At step 320, the process 300 produces a voltage that is proportional to the sampled RF input signal at a detector. At step 330, the process 300 determines whether a signal level of the RF input signal is above a detection threshold value for flatness compensation for an RF output signal at a voltage comparator.

If the signal level of the RF input signal is above the detection threshold, a frequency-response flatness compensation sequence is initiated at step 340, where the process 300 divides the frequency of the RF input signal down to a value that represents the RF input signal for processing by a microcontroller at a prescaler. At step 350, an output of the prescaler representing the RF input signal is measured to generate a measured signal for the microcontroller, and at step 360, the process 300 selects a value stored in a lookup table that is closest to a selected sample point from the measured signal (or an interpolation between the closest two sample points).

The process 300 then performs the gain control sequence. At step 370, the process 300 reduces a gain of variable gain amplifier by the value in the lookup table selected by the microcontroller that is closest to the selected sample point (or an interpolation between the closest two sample points) by the digital/analog converter. In this manner, the RF output signal exhibits a frequency response corrected for flatness errors at a desired operational frequency. As noted, the compensation value may be that closest to value stored in the lookup table, or a value interpolated in software between the lookup table values above and below the measured frequence to increase the effective resolution.

In a further embodiment, the present invention is a scheme for automatic frequency detection and input, where a power meter is applied to help ensure that a constant power level exists between the input power and a given or desired power output of an amplifier system. Power meters are useful for automatically tracking a relationship between input and output power of a device over a range of power levels. As noted above, some power amplifiers have built-in power meters and components performing automatic level control (ALC) functions to maintain a constant power level, at least in part (as to the former) to mitigate the problem of requiring a manual user input of a frequency of an input signal. While it is common for power meters to also have a calibration table that enables compensation for a lack of flatness in frequency, users must still input (manually or via other means) the frequency to be used for a given power output to the power meter. If the power meter is routinely used for measurements of signals with multiple frequencies, then the frequency must be provided as an input to the instrument prior to subsequent measurements. The present invention provides an approach for automatic frequency input that is specific to the use of power meters for regulating power levels.

In a standard application of a power meter, an RF signal is applied to a sensor, whose output is a signal proportional to the RF input power. This output is provided to a processor for conversion to a power reading. As a part of the conversion process, a calibration value that is a function of frequency is used to obtain the optimum measurement accuracy. That calibration value is typically found on a label on the sensor (value versus frequency), or in a look-up table saved inside the power meter. Depending on the implementation, the operator either manually enters the frequency or calibration value into the power meter via a control or keypad, or via a computer interface connected to the power meter via an external interface. For an instrument using a digital implementation, the calibration data is typically contained in the memory of the processor. Whenever the frequency of the input signal is changed, the instrument must be updated accordingly to obtain the optimum measurement accuracy.

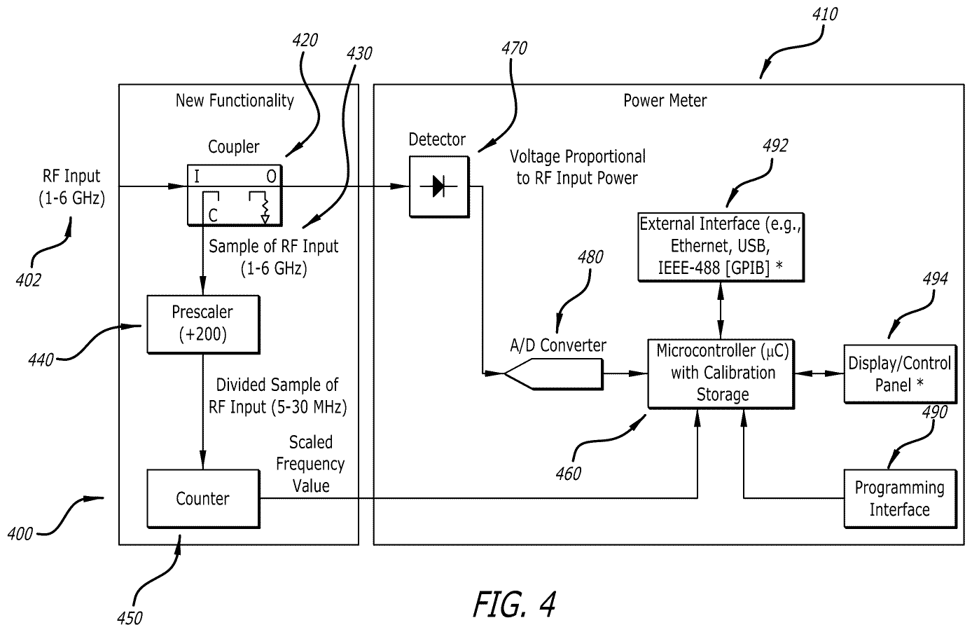

FIG. 4 is diagram illustrating a circuit 400 that provides an automatic frequency input function for applicability with the use of a power meter 410 according to this embodiment of the present invention. Power meters typically have an external computer interface 492, control panel or display 494, or other programming interface 490, through with frequency values are manually entered, among other functions attendant to power meter operation. With the novel functionality of the present invention, that frequency value is determined automatically. It is to be noted that any amplitude and frequency notations in FIG. 4 are provided for example only, and that the actual configuration and values will vary by the application within which the circuit 400 is implemented. It is therefore to be understood that the present invention is not to be limited to any such notation or example illustrated in the drawings or discussed herein.

The following discussion again refers to the example from above, where the frequency range is 1-6 GHz (1,000-6,000 MHz). It is to be understood however that the inventive concept and this embodiment are not to be limited to any particular frequency range discussed herein.

In the circuit 400 of FIG. 4, an RF input signal 402 is applied to a coupler 420, where a sample 430 of the RF input signal 402 is captured and fed to a prescaler 440. The purpose of the prescaler 440 is to divide the high frequency of the RF input signal 402 down to a value that can be more easily processed by other digital circuit elements in the circuit 400 and power meter 410. In this example, the prescaler 440 divides the 1-6 GHz RF input signal 410 down to 5-30 MHz so that it can be processed, or measured, by a counter 450. The frequency value is then sent to a microcontroller 460. Note that the counter may be incorporated in the microcontroller.

The frequency value is then used as follows. A sample of the RF input signal 402 from the coupler 420 is applied to a detector 470, which generates a voltage that is proportional to a power level of the input. This voltage is applied to an analog-to-digital converter 480, the output of which is fed to the microcontroller 460. The conversion of the detected voltage to power level as a function of frequency is performed automatically, by finding the value in a look-up table in the microcontroller 460 that represents the desired output power level as a function of the frequency at the detected voltage. It is to be understood that the automatic frequency input function of the present invention may be implemented in amplifier systems with different types of waveforms comprising the RF input signal 402. For example, it may be implemented with continuous wave or pulsed waveforms, or waveforms with various types of modulation.

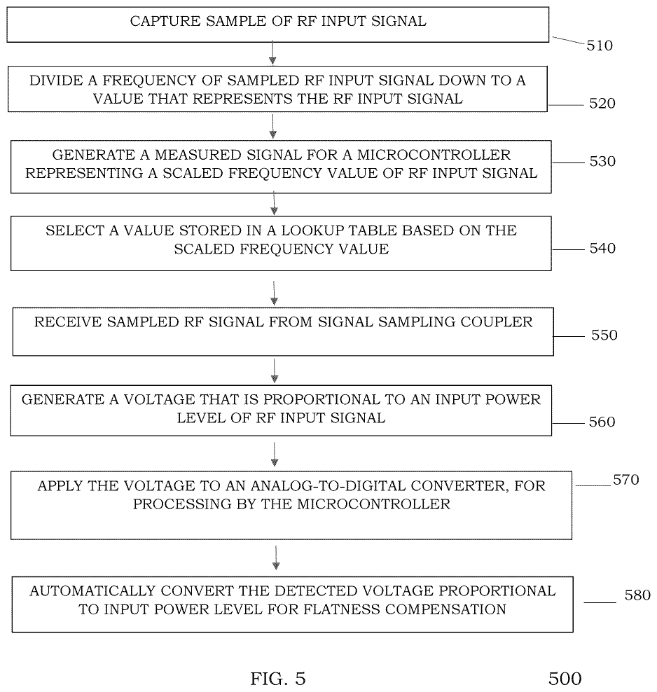

FIG. 5 is a flowchart of steps in a process 500 of performing the present invention according to the embodiment of FIG. 4 for automatic frequency input function to power meters. The process 500 begins at step 510 by capturing a sample of a RF input signal at a signal sampling coupler. This sample is passed to a prescaler, where at step 520 the frequency of the sampled RF input signal is divided down to a value that represents the RF input signal for processing by a microcontroller and other digital circuit elements. At step 530, a counter measures an output of the prescaler representing the RF input signal, and generates a measured signal for the microcontroller representing a scaled frequency value of the RF input signal.

At step 540, the microcontroller selects a value stored in a lookup table based on the scaled frequency value, and at step 550, a detector receives the sampled RF signal from the signal sampling coupler. The coupler generates a voltage that is proportional to an input power level of the RF input signal at step 560, and applies the voltage to an analog-to-digital converter, wherein the output of analog-to-digital converter is provided to the microcontroller at step 570.

The microcontroller takes the digital value of detected voltage that is proportional to the input power and applies frequency compensation using the value in the lookup table corresponding to that frequency. The corrected power level is then presented to the operator and/or using system via the external interface 492 or display panel 494.

In still a further embodiment, the present invention is a scheme for performing frequency-response flatness compensation and gain control functions where circuit elements that perform the automatic level control function are present to maintain a constant power level between input and output signals, and which themselves affect a gain of the overall system. One issue with built-in power output control features is that they may work quite well at a specific frequency (typically, the frequency at which they are calibrated), but exhibit errors at other frequencies due at least to imperfections in the response as a function of the flatness of the power meter and automatic level control components themselves, as these often limit the overall flatness of the system. Also, the speed at which an automatic level control function operates is often limited by the nature of the RF signal. For example, if the automatic level control function operates at a speed that is fast relative to the frequency of amplitude modulation, then the automatic level control function would “strip-off” that modulation.

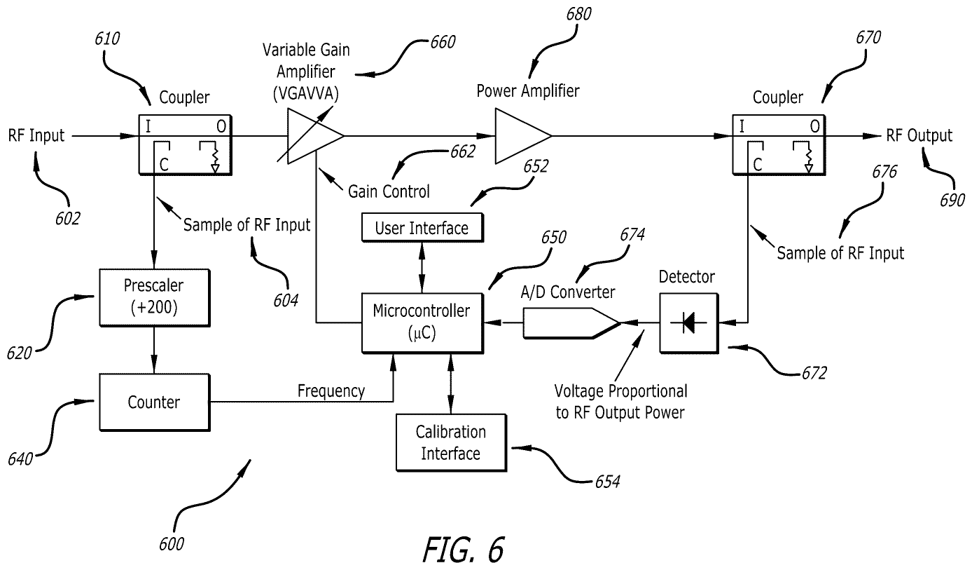

FIG. 6 is a diagram illustrating a circuit 600 for performing frequency-response flatness compensation and corresponding gain control in wideband or broadband amplifiers, or other applications and systems in electronics, in which automatic level control components are included. In performance of amplifier frequency-response flatness correction according to FIG. 6, detection of a signal frequency and automatic frequency input is accomplished similar to the manner described above with respect to FIG. 4 and FIG. 5. For example, the circuit 600 includes a signal sampling coupler 610, coupled to the RF input and receiving the RF input signal 602, that provides a sample 604 of the RF input signal 602 to components that determine the frequency of that signal. Those components comprise at least the prescaler 620 and counter 640, whose functions are discussed above. The frequency determined by these circuit elements is provided to a microcontroller 650 and processed by internal/on-board software. A memory of the microcontroller 650 includes a lookup table that was prepared following a prior frequency-response calibration of the amplifier system. During that calibration, the uncorrected frequency response of the amplifier is saved in a calibration lookup table. Then during the operation of the amplifier, the measured frequency of the RF input signal 602 is applied to the lookup table, and a gain 662 needed to adjust a variable gain amplifier 660 to correct the inherent flatness error of a power amplifier 680 at the measured frequency is determined for gain control.

For automatic level control frequency-response flatness correction and corresponding gain control, a second lookup table in memory of the microcontroller 650 contains the frequency response of an automatic level control circuit, which may comprise one or more of an output coupler 670 (for capturing a sample 676 of an RF output signal 690), a detector 672, and analog-digital converter 674, and other related circuit elements. During the operation of the power amplifier 680, the measured frequency of the RF input signal 602 is applied to the lookup table, and the calculated power is corrected by the frequency response of the circuit elements comprising the automatic level control function (such as the output coupler 670 and detector 672, etc.) from the second lookup table. The gain 662 of a variable gain amplifier 660 is then adjusted according to the value in the second lookup table to account for flatness errors due to the ALC components to achieve a proportional signal 690 at the RF output. The improvement in the accuracy of the function of a power meter from automatic frequency input results in a corresponding improvement in the accuracy of the components comprising the automatic level control function, at least since the frequency response of those circuit elements, and corresponding gain adjustment, is informed by the calculated power level of the RF input signal 602.

Note that the correction of the flatness of the amplifier gain and power meter functions can be used simultaneously, but correction of the flatness of the amplifier gain and correction of flatness due to the automatic level control function cannot be used simultaneously, as there would be a conflict over the control of the variable gain amplifier.

Note further that there are many circuit elements which may be utilized to achieve automatic level control in a power amplifier. Accordingly, neither the present invention nor this specification are intended to be limited to any specific circuit elements for automatic level control described herein.

The microcontroller 650 may also have one or more interfaces, such as a user interface 652 and a calibration interface 654, for performing various functions attendant to its operation.

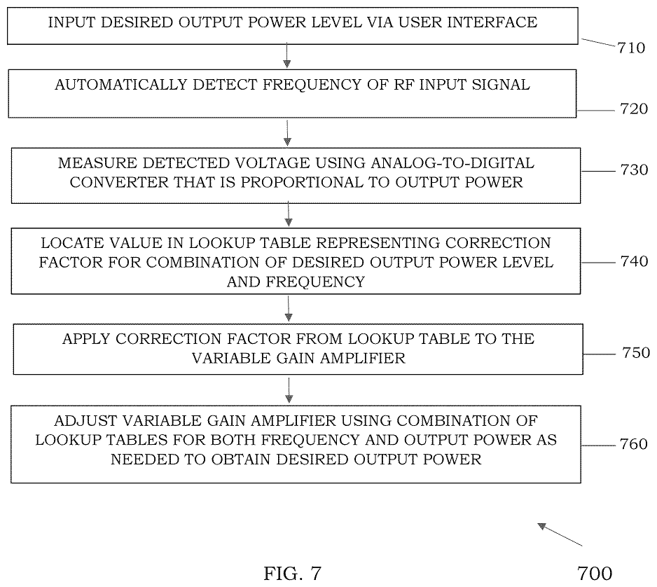

FIG. 7 is a flowchart comprising steps in a process 700 of performing the present invention according to the embodiment of FIG. 6 for frequency-response flatness compensation and gain control to correct inherent flatness errors due to an automatic level control function in an amplifier circuit. The process 700 begins at step 710 by the user inputting the desired output power level, for example via a user interface. The frequency of the radio frequency (RF) input signal is then automatically detected in step 720, generating an automatic frequency input for the power meter. At step 730, the detected voltage that is proportional to the output power of the RF signal is measured with an analog-to-digital converter. At step 740 this measurement is provided as an input to a microcontroller to locate the value in a lookup table representing a correction factor for a combination of the desired output power level and frequency.

The process 700 at step 750 then applies the correction factor from the lookup table to a variable gain amplifier, and at step 760 adjusts the variable gain amplifier using a combination of the lookup tables for both frequency and output power as needed to obtain the desired output power.

The present invention may be styled as follows:
1. A circuit, comprising:
a signal sampling coupler, coupled to a voltage detector and a voltage comparator, wherein the voltage comparator receives a voltage that is proportional to a sampled RF input signal generated by the detector, and determines whether a signal level of the RF input signal is above a detection threshold value for flatness compensation for a RF output signal;
a signal processing coupler, coupled to a prescaler and a counter, wherein the prescaler divides a frequency of the RF input signal down to a value that represents the RF input signal for processing by the counter and a microcontroller where the signal level is above the detection threshold value, the counter measuring an output of the prescaler representing the RF input signal to generate a measured signal frequency for the microcontroller, the microcontroller selecting a value stored in a lookup table that applies to the measured signal frequency; and
a digital-to-analog converter coupled to a variable gain amplifier, wherein a gain of the variable gain amplifier is adjusted by the value in the lookup table selected by the microcontroller that is applicable to the selected sample point by the digital-to-analog converter to obtain a flat frequency response in the RF output signal.
2. The circuit of claim 1, wherein if the signal level is below the threshold, the microcontroller sets the gain of the variable gain amplifier via the digital-to-analog converter to a nominal value so that a power amplifier functions without frequency compensation
3. The circuit of claim 1, wherein the signal sampling coupler receives the RF input signal and captures a sample of the RF input signal.
4. The circuit of claim 1, wherein the signal processing coupler receives the sample of the RF input signal from the signal sampling coupler where the signal level is above the detection threshold value.
5. The circuit of claim 1, wherein an output of the variable gain amplifier is provided to an amplifier.
6. The circuit of claim 1, further comprising a pre-processing calibration sequence, in which a network analyzer is configured to measure a frequency response over a selected frequency range and generate a frequency response file containing a magnitude of a gain at multiple points across that range
7. The circuit of claim 5, wherein the frequency response file is provided to the microcontroller via a programming interface and stored as the lookup table in the microcontroller.
8. The circuit of claim 5, further comprising repeating the pre-processing calibration sequence at multiple calibration points to produce a smoother overall frequency response to account for variations in gain at frequencies between the calibration points stored in the lookup table.
9. An amplifier, comprising:
a radio frequency (RF) input signal;
an automatic detection circuit, the automatic detection circuit including:
   a signal sampling coupler,
   a voltage detector, and
   a voltage comparator,
   wherein the voltage comparator receives a voltage that is proportional to a sampled RF input signal generated by the detector, and determines whether a signal level of the RF input signal is above a detection threshold value for flatness compensation for a RF output signal;
a flatness compensation circuit, the flatness compensation circuit including
   a signal processing coupler,
   a prescaler, and
   a counter,
   wherein the prescaler divides a frequency of the RF input signal down to a value that represents the RF input signal for processing by the counter and a microcontroller where the signal level is above the detection threshold value, the counter measuring an output of the prescaler representing the RF input signal to generate measured signal for the microcontroller, the microcontroller selecting a value stored in a lookup table that is applicable to the selected sample point from the measured signal;
a gain control circuit, the gain control circuit including
   a digital/analog converter, and
   a variable gain amplifier,
   wherein the variable gain amplifier is adjusted by the microcontroller in response to the flatness compensation circuit to correct inherent flatness errors at a desired operational frequency, by controlling a gain of the variable gain amplifier by the value in the lookup table selected by the microcontroller that is applicable to the selected sample point by the digital/analog converter; and
a radio frequency (RF) output signal exhibiting a frequency response corrected for flatness at the desired operational frequency.
10. The amplifier of claim 9, wherein if the signal level is below the threshold, the microcontroller sets the gain of the variable gain amplifier via the digital-to-analog converter to a nominal value so that an amplifier functions without frequency compensation
11. The amplifier of claim 9, wherein the signal sampling coupler receives the RF input signal and captures a sample of the RF input signal.
12. The amplifier of claim 9, wherein the signal processing coupler receives the sample of the RF input signal from the signal sampling coupler where the signal level is above the detection threshold value.
13. The amplifier of claim 9, further comprising a pre-processing calibration sequence, in which a network analyzer is configured to measure a frequency response over a selected frequency range and generate a frequency response file containing an amplitude of a gain at multiple points across that range
14. The amplifier of claim 13, wherein the frequency response file is provided to the microcontroller via a programming interface and stored as the lookup table in the microcontroller.
15. The amplifier of claim 13, further comprising repeating the pre-processing calibration sequence at multiple calibration points to produce a smoother overall frequency response to account for variations in gain at frequencies between the calibration points stored in the lookup table.
16. A method, comprising:
capturing a sample of a radio frequency (RF) input signal at a first coupler;
producing a voltage that is proportional to the sampled RF input signal at a detector;
determining whether a signal level of the RF input signal is above a detection threshold value for flatness compensation for a RF output signal at a voltage comparator;
dividing a frequency of the RF input signal down to a value that represents the RF input signal for processing by a microcontroller at a prescaler;
measuring an output of the prescaler representing the RF input signal to generate a measured signal frequency for the microcontroller;
selecting a value stored in a lookup table that is closest to a selected sample point from the measured signal frequency; and
adjusting a gain of a variable gain amplifier by the value in the lookup table selected by the microcontroller closest to the selected sample point by the digital/analog converter, wherein the RF output signal exhibits a frequency response corrected for flatness errors at a specific operational frequency.
17. The method of claim 16, wherein if the signal level is below the threshold, the microcontroller sets the gain of the variable gain amplifier via the digital-to-analog converter to a nominal value so that a power amplifier operates without frequency compensation.
18. The method of claim 16, wherein the first coupler is a signal sampling coupler that receives the RF input signal, captures the sample of the RF input signal, and provides the sample of the RF input signal to the voltage detector.
19. The method of claim 16, further comprising receiving the sample of the RF input signal at a second coupler where the signal level is above the detection threshold value.
20. The method of claim 19, wherein the second coupler is a signal processing coupler that provides the sample of the RF input signal to the prescaler and the counter.
21. The method of claim 16, wherein an output of the variable gain amplifier is provided to an amplifier.
22. The method of claim 16, further comprising a pre-processing calibration sequence, in which a network analyzer is configured to measure a frequency response over a selected frequency range and generate a frequency response file containing an amplitude of a gain at multiple points across that range.
23. The method of claim 22, wherein the frequency response file is provided to the microcontroller via a programming interface and stored as the lookup table in the microcontroller.
24. The method of claim 22, further comprising repeating the pre-processing calibration sequence at multiple calibration points to produce a smoother overall frequency response to account for variations in gain at frequencies between the calibration points stored in the lookup table.

In another embodiment, the present invention may be styled as:
1. A circuit for ensuring a desired output power of an amplifier is proportional to a power level in a RF input signal, comprising:
a signal sampling coupler, wherein the signal sampling coupler receives a radio frequency (RF) input signal and captures a sample of the RF input signal,
a prescaler, coupled to an output of the signal sampling coupler, wherein the prescaler receives a sampled RF input signal and divides a frequency of the RF input signal down to a value that represents the RF input signal;
a counter, coupled to an output of the prescaler, wherein the counter measures the output of the prescaler representing the RF input signal, and generates a measured signal for the microcontroller representing a scaled frequency value, the microcontroller configured to select a value stored in a lookup table based on the scaled frequency value;
a detector, coupled to and receiving the sampled RF signal from the signal sampling coupler, the detector configured to generate a voltage that is proportional to an input power level of the RF input signal, and apply the voltage to an analog-to-digital converter, wherein the output of analog-to-digital converter is provided to the microcontroller,
wherein the microcontroller automatically converts the detected voltage that is proportion to an output power level for flatness compensation, by locating a value that represents a desired output power level as a function of the frequency at the detected voltage in the lookup table in the microcontroller,
and, wherein the value is applied to perform a gain control function to match an input power level in the RF input signal to the desired output power level in one or more automatic level control functions.
2. An amplifier, comprising:
a radio frequency (RF) input signal;
an automatic frequency input circuit, the automatic frequency input circuit including
   a signal sampling coupler, wherein the signal sampling coupler receives a radio frequency (RF) input signal and captures a sample of the RF input signal,
   a prescaler, coupled to an output of the signal sampling coupler, wherein the prescaler receives a sampled RF input signal and divides a frequency of the RF input signal down to a value that represents the RF input signal;
   a counter, coupled to an output of the prescaler, wherein the counter measures the output of the prescaler representing the RF input signal, and generates a measured signal for the microcontroller representing a scaled frequency value, the microcontroller configured to select a value stored in a lookup table based on the scaled frequency value; and
a power level conversion circuit, the power level conversion circuit including
   a detector, coupled to and receiving the sampled RF signal from the signal sampling coupler, the detector configured to generate a voltage that is proportional to an input power level of the RF input signal, and apply the voltage to an analog-to-digital converter, wherein the output of analog-to-digital converter is provided to the microcontroller,
   wherein the microcontroller automatically converts the detected voltage that is proportional to an output power level for flatness compensation, by locating a value that represents a desired output power level as a function of the frequency at the detected voltage in the lookup table in the microcontroller,
and wherein the value is applied to perform a gain control function to match an input power level in the RF input signal to the desired output power level.
3. A method, comprising:
capturing a sample of a radio frequency (RF) input signal at a signal sampling coupler;
dividing a frequency of the sampled RF input signal down to a value that represents the RF input signal at a prescaler;
measuring an output of the prescaler representing the RF input signal;
generating a measured signal for a microcontroller representing a scaled frequency value of the RF input signal;
selecting a value stored in a lookup table based on the scaled frequency value;
receiving the sampled RF signal from the signal sampling coupler;
generating a voltage that is proportional to an input power level of the RF input signal;
applying the voltage to an analog-to-digital converter, wherein the output of analog-to-digital converter is provided to the microcontroller; and
automatically converting the detected voltage that is proportional to an output power level for flatness compensation, by locating a value that represents a desired output power level as a function of the frequency at the detected voltage in the lookup table in the microcontroller,
wherein the value is applied to perform a gain control function to match an input power level in the RF input signal to the desired output power level.

In a further embodiment, the present invention may be styled as:
1. An amplifier, comprising:
a radio frequency (RF) input signal;
an automatic frequency input circuit, including a signal sampling coupler, a prescaler, and a counter, wherein the counter measures an output of the prescaler representing the RF input signal, and generates a measured signal for a microcontroller representing a scaled frequency value, the microcontroller configured to select a first value stored in a lookup table based on the scaled frequency value;
an automatic level control circuit, including a coupler, a detector, and an analog-to-digital converter, wherein a second value is located in the look-up table of the microcontroller that represents a desired output power as a function of frequency at a voltage detected by the detector, to automatically convert the voltage to a power level as a function of frequency;
a frequency-response compensation and gain control circuit at least including a variable gain amplifier, wherein a second lookup table in the memory of the microcontroller stores an expected frequency response of the automatic level control circuit at the power level, and wherein a gain of the variable gain amplifier is reduced by a gain value in the second lookup table based on the expected frequency response of the automatic level control circuit; and
a RF output signal corrected for flatness at the desired output power.
2. A circuit, comprising:
a signal sampling coupler, a prescaler, and a counter, that together comprise an automatic frequency input sequence for an amplifier circuit, wherein the counter measures an output of the prescaler representing a sampled radio frequency (RF) input signal, and generates a measured signal for a microcontroller representing a scaled frequency value, the microcontroller configured to select a first value stored in a lookup table based on the scaled frequency value;
a coupler, a detector, and an analog-to-digital converter, that together perform automatic level control to maintain a consistent power level of the amplifier, wherein a second value is located in a look-up table of the microcontroller that represents the desired output power as a function of frequency at a voltage detected by the detector, to automatically convert the voltage to a power level as a function of frequency; and
a variable gain amplifier, wherein a second lookup table in the memory of the microcontroller stores an expected frequency response of the coupler, the detector, and the analog-to-digital converter performing the automatic level control at the power level, and wherein a gain of the variable gain amplifier is reduced by a gain value in the second lookup table based on the expected frequency response, so that a RF output signal is corrected for flatness at the desired output power.
3. A method, comprising:
automatically detecting a frequency of a radio frequency (RF) input signal and generating an automatic frequency input for a power meter;
automatically controlling a power level of an amplifier, by generating a detected voltage that is proportional to an input power of the RF input signal, applying the voltage to an analog-to-digital converter for input to a microcontroller, and locating a value in a lookup table in a memory of the microcontroller that represents a desired output power as a function of the frequency at the detected voltage; and
adjusting a variable gain amplifier, wherein a second lookup table in the memory of the microcontroller stores an expected frequency response of circuit elements performing the automatically controlling a power level, and wherein a gain of the variable gain amplifier is reduced by a gain value in the second lookup table based on the expected frequency response.

The systems and methods of the present invention may be implemented in many different performance and design environments. For example, they may be implemented in conjunction with any type of RF or microwave circuit in which power is to be combined (or divided). The present invention may itself be considered as an amplifier system that includes a circuit 100, as well as a circuit 100 that is usable in an amplifier system. Additionally, the present invention may be considered as part of a broader application, including radar transmitters, electronic warfare systems, testing applications, and any other system in which high-frequency signal combining or dividing is desired. Therefore, it is to be understood that the present invention may further include system components and devices for implementing the circuit 100 in different hardware environments. For example, the present invention may be embodied or arranged on one or more printed circuit boards (PCBs), and may also include controller(s), CPUs, driver(s), heat sinks, and other components, assemblies, or sub-assemblies for functioning in the desired hardware environment.

The foregoing descriptions of embodiments of the present invention have been presented for the purposes of illustration and description. It is not intended to be exhaustive or to limit the invention to the precise forms disclosed. Accordingly, many alterations, modifications and variations are possible in light of the above teachings, may be made by those having ordinary skill in the art without departing from the spirit and scope of the invention. For example, counters may be part of, or on-board, a microcontroller, and therefore not separate circuit elements. Also, the embodiments of the present invention may be integrated into other electronics systems, in addition to power amplifiers. It is therefore intended that the scope of the invention be limited not by this detailed description. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus, if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a sub-combination or variation of a sub-combination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

1. A circuit, comprising:
a signal sampling coupler, coupled to a voltage detector and a voltage comparator, wherein the voltage comparator receives a voltage that is proportional to a sampled RF input signal generated by the detector, and determines whether a signal level of the RF input signal is above a detection threshold value for flatness compensation for a RF output signal;
a signal processing coupler, coupled to a prescaler and a counter, wherein the prescaler divides a frequency of the RF input signal down to a value that represents the RF input signal for processing by the counter and a microcontroller where the signal level is above the detection threshold value, the counter measuring an output of the prescaler representing the RF input signal to generate a measured signal frequency for the microcontroller, the microcontroller selecting a value stored in a lookup table that applies to the measured signal frequency; and
a digital-to-analog converter coupled to a variable gain amplifier, wherein a gain of the variable gain amplifier is adjusted by the value in the lookup table selected by the microcontroller that is applicable to the selected sample point by the digital-to-analog converter to obtain a flat frequency response in the RF output signal.

2. The circuit of claim 1, wherein if the signal level is below the threshold, the microcontroller sets the gain of the variable gain amplifier via the digital-to-analog converter to a nominal value so that a power amplifier functions without frequency compensation

3. The circuit of claim 1, wherein the signal sampling coupler receives the RF input signal and captures a sample of the RF input signal.

4. The circuit of claim 1, wherein the signal processing coupler receives the sample of the RF input signal from the signal sampling coupler where the signal level is above the detection threshold value.

5. The circuit of claim 1, wherein an output of the variable gain amplifier is provided to an amplifier.

6. The circuit of claim 1, further comprising a pre-processing calibration sequence, in which a network analyzer is configured to measure a frequency response over a selected frequency range and generate a frequency response file containing a magnitude of a gain at multiple points across that range

7. The circuit of claim 5, wherein the frequency response file is provided to the microcontroller via a programming interface and stored as the lookup table in the microcontroller.

8. The circuit of claim 5, further comprising repeating the pre-processing calibration sequence at multiple calibration points to produce a smoother overall frequency response to account for variations in gain at frequencies between the calibration points stored in the lookup table.

9. An amplifier, comprising:
a radio frequency (RF) input signal;
an automatic detection circuit, the automatic detection circuit including:
a signal sampling coupler,
a voltage detector, and
a voltage comparator,
wherein the voltage comparator receives a voltage that is proportional to a sampled RF input signal generated by the detector, and determines whether a signal level of the RF input signal is above a detection threshold value for flatness compensation for a RF output signal;
a flatness compensation circuit, the flatness compensation circuit including
a signal processing coupler,
a prescaler, and
a counter,
wherein the prescaler divides a frequency of the RF input signal down to a value that represents the RF input signal for processing by the counter and a microcontroller where the signal level is above the detection threshold value, the counter measuring an output of the prescaler representing the RF input signal to generate measured signal for the microcontroller, the microcontroller selecting a value stored in a lookup table that is applicable to a selected sample point from the measured signal;
a gain control circuit, the gain control circuit including
a digital/analog converter, and
a variable gain amplifier,
wherein the variable gain amplifier is adjusted by the microcontroller in response to the flatness compensation circuit to correct inherent flatness errors at a desired operational frequency, by controlling a gain of the variable gain amplifier by the value in the lookup table selected by the microcontroller that is applicable to the selected sample point by the digital/analog converter; and
a radio frequency (RF) output signal exhibiting a frequency response corrected for flatness at the desired operational frequency.

10. The amplifier of claim 9, wherein if the signal level is below the threshold, the microcontroller sets the gain of the variable gain amplifier via the digital-to-analog converter to a nominal value so that an amplifier functions without frequency compensation

11. The amplifier of claim 9, wherein the signal sampling coupler receives the RF input signal and captures a sample of the RF input signal.

12. The amplifier of claim 9, wherein the signal processing coupler receives the sample of the RF input signal from the signal sampling coupler where the signal level is above the detection threshold value.

13. The amplifier of claim 9, further comprising a pre-processing calibration sequence, in which an analyzer is configured to measure a frequency response over a selected frequency range and generate a frequency response file containing an amplitude of a gain at multiple points across that range

14. The amplifier of claim 13, wherein the frequency response file is provided to the microcontroller via a programming interface and stored as the lookup table in the microcontroller.

15. The amplifier of claim 13, further comprising repeating the pre-processing calibration sequence at multiple calibration points to produce a smoother overall frequency response to account for variations in gain at frequencies between the calibration points stored in the lookup table.

16. A method, comprising:
capturing a sample of a radio frequency (RF) input signal at a first coupler;
producing a voltage that is proportional to the sampled RF input signal at a detector;
determining whether a signal level of the RF input signal is above a detection threshold value for flatness compensation for a RF output signal at a voltage comparator;
dividing a frequency of the RF input signal down to a value that represents the RF input signal for processing by a microcontroller at a prescaler;
measuring an output of the prescaler representing the RF input signal to generate a measured signal frequency for the microcontroller;
selecting a value stored in a lookup table that is closest to a selected sample point from the measured signal frequency; and
adjusting a gain of a variable gain amplifier by the value in the lookup table selected by the microcontroller applicable to the selected sample point by the digital/analog converter, wherein the RF output signal exhibits a frequency response corrected for flatness errors at a specific operational frequency.

17. The method of claim 16, wherein if the signal level is below the threshold, the microcontroller sets the gain of the variable gain amplifier via the digital-to-analog converter to a nominal value so that a power amplifier operates without frequency compensation.

18. The method of claim 16, wherein the first coupler is a signal sampling coupler receives the RF input signal, captures the sample of the RF input signal, and provides the sample of the RF input signal to the voltage detector.

19. The method of claim 16, further comprising receiving the sample of the RF input signal at a second coupler where the signal level is above the detection threshold value.

20. The method of claim 19, wherein the second coupler is a signal processing coupler that provides the sample of the RF input signal to the prescaler and the counter.

21. The method of claim 16, wherein an output of the variable gain amplifier is provided to an amplifier.

22. The method of claim 16, further comprising a pre-processing calibration sequence, in which a network analyzer is configured to measure a frequency response over a selected frequency range and generate a frequency response file containing an amplitude of a gain at multiple points across that range.

23. The method of claim 22, wherein the frequency response file is provided to the microcontroller via a programming interface and stored as the lookup table in the microcontroller.

24. The method of claim 22, further comprising repeating the pre-processing calibration sequence at multiple calibration points to produce a smoother overall frequency response to account for variations in gain at frequencies between the calibration points stored in the lookup table.
